(19) United States
(12) Patent Application Publication
(10) Pub. No.: US 2021/0074519 A1
(43) Pub. Date: Mar. 11, 2021

(54) HEAT MEDIUM CIRCULATION SYSTEM AND SUBSTRATE PROCESSING APPARATUS

(71) Applicant: Tokyo Electron Limited, Tokyo (JP)

(72) Inventors: Masaru ISAGO, Kurokawa-gun (JP); Takashi KITAZAWA, Kurokawa-gun (JP)

(21) Appl. No.: 17/011,668

(22) Filed: Sep. 3, 2020

(30) Foreign Application Priority Data
Sep. 11, 2019 (JP) 2019-165388

(51) Int. Cl. H01J 37/32; H01L 21/67; H01J 37/305

(52) U.S. Cl. CPC H01J 37/32522; H01L 21/67069; H01J 37/3053; H01L 21/67248

(57) ABSTRACT

A heat medium circulation system including: a resin pipe forming at least a portion of a circulation flow path for circulating a heat medium to a temperature control target; a cover surrounding an outer peripheral surface of the resin pipe; and an exhaust pipe connected to a space between the resin pipe and the cover so as to exhaust the heat medium permeating through the resin pipe and released to the space, wherein the cover includes an air supply port configured to introduce air into the space between the resin pipe and the cover while the heat medium is exhausted from the exhaust pipe.

### CROSS-REFERENCE TO RELATED APPLICATION

This application is based upon and claims the benefit of priority from Japanese Patent Application No. 2019-165388, filed on Sep. 11, 2019, the entire contents of which are incorporated herein by reference.

### TECHNICAL FIELD

The present disclosure relates to a heat medium circulation system and a substrate processing apparatus.

### BACKGROUND

In a substrate processing apparatus or the like for processing a substrate such as a semiconductor wafer (hereinafter referred to as a “wafer”), when controlling a temperature of a member in the apparatus, a circulation flow path for circulating a heat medium to the member which is the temperature control target is formed. In the circulation flow path for circulating the heat medium, a highly flexible resin pipe may be used.

When a resin pipe is used in a portion of the circulation flow path for circulating a high-temperature heat medium, a component of the heat medium flowing in the resin pipe may permeate through the resin pipe and may be released as a permeating gas around the pipe. The release of the permeating gas around the pipe causes environmental pollution and thus is not desirable.

There has been proposed a technique for airtightly surrounding an outer circumferential surface of an inner resin pipe using an outer pipe, connecting an exhaust pipe to the airtightly surrounded space between the inner pipe and the outer pipe to exhaust the permeating gas, which permeates the inner pipe to be released through the inner pipe, from the exhaust gas (see, e.g., Patent Document 1).

### PRIOR ART DOCUMENT

### [Patent Document]

Patent Document 1: Japanese Laid-Open Patent Publication No. 2001-297967

### SUMMARY

According to embodiments of the present disclosure, there is provided a heat medium circulation system including: a resin pipe forming at least a portion of a circulation flow path for circulating a heat medium to a temperature control target; a cover surrounding an outer peripheral surface of the resin pipe; and an exhaust pipe connected to a space between the resin pipe and the cover so as to exhaust the heat medium permeating through the resin pipe and released to the space, wherein the cover includes an air supply port configured to introduce air into the space between the resin pipe and the cover while the heat medium is exhausted from the exhaust pipe.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a cross-sectional view schematically illustrating an exemplary configuration of a plasma processing apparatus according to an embodiment.

FIG. 2 is a view schematically illustrating a conventional circulation flow path for circulating a heat medium, in which a shower head is a temperature control target member.

FIG. 3 is a view schematically illustrating a configuration of a pipe according to the embodiment.

FIG. 4 is a view schematically illustrating a configuration of a pipe according to the embodiment.

FIG. 5 is a view illustrating a modification of a cover.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, various embodiments will be described in detail with reference to the drawings. In addition, in each of the drawings, the same or corresponding parts will be denoted by the same reference numerals.

In order to prevent permeating gas from being diffused to the surroundings, it is conceivable to hermetically seal the periphery of a pipe using an outer pipe (cover) and to exhaust the closed space between the pipe and the cover using the pump. However, when the distance between the closed space and the pump is large, the conductance becomes worse, and thus it is difficult to sufficiently exhaust the permeating gas within the closed space. In addition, when the pipe is disposed in the air atmosphere, the pressure difference between the depressurized closed space and the air atmosphere may cause the pipe and the cover to come close to each other, causing the closed space to shrink. Thus, there is a possibility that exhaust efficiency of the permeating gas may decrease. Therefore, improving the exhaust efficiency of the permeating gas permeating through the resin pipe has been needed.

### [Configuration of Substrate Processing Apparatus]

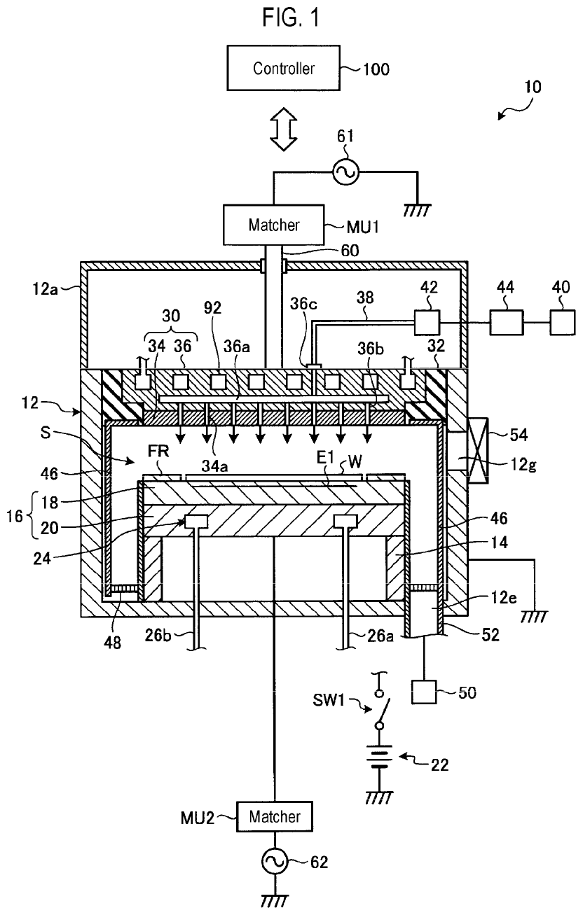

First, the configuration of a substrate processing apparatus according to an embodiment will be described. The substrate processing apparatus is an apparatus that performs predetermined substrate processing on a substrate such as a wafer. In the present embodiment, a case in which the substrate processing apparatus is a plasma processing apparatus 10 that performs processing such as plasma etching on the wafer W, as a substrate, will be described as an example. FIG. 1 is a cross-sectional view schematically illustrating an exemplary configuration of a plasma processing apparatus 10 according to the embodiment. The plasma processing apparatus 10 illustrated in FIG. 1 is configured as a plasma-etching apparatus using capacitively coupled plasma (CCP). The plasma processing apparatus 10 includes a substantially cylindrical processing container 12. The processing container 12 is made of, for example, aluminum. In addition, the surface of the processing container 12 is anodized.

A stage 16 is provided in the processing container 12. The stage 16 includes an electrostatic chuck 18 and a base 20. A top surface of the electrostatic chuck 18 serves as a placement surface on which a workpiece to be subjected to plasma processing is placed. In the present embodiment, the wafer W as a workpiece is placed on the top surface of the electrostatic chuck 18. The base 20 is substantially disk shaped, and a main portion thereof is made of a conductive metal such as aluminum. The base 20 forms a lower electrode. The base 20 is supported by a support 14. The support 14 is a cylindrical member extending from a bottom portion of the processing container 12.

On the base 20, the electrostatic chuck 18 is provided. The electrostatic chuck 18 attracts the wafer W by electrostatic force such as Coulomb force so as to hold the wafer W. The electrostatic chuck 18 has an electrode E1 for electrostatic attraction in a ceramic body. A DC power supply 22 is electrically connected to the electrode E1 via a switch SW1. The attraction force for holding the wafer W depends on a value of a DC voltage applied from the DC power supply 22. In addition, a heat transfer gas (e.g., He gas) may be supplied to a space between the top surface of the electrostatic chuck 18 and a rear surface of the wafer W by a heat transfer gas supply mechanism and a gas supply line (not illustrated).

In the stage 16, a focus ring FR is disposed around the wafer W on the electrostatic chuck 18. The focus ring FR is provided in order to improve the uniformity of plasma processing. The focus ring FR is made of a material appropriately selected according to the plasma processing to be performed. For example, the focus ring FR may be made of silicon or quartz.

Inside the base 20, a coolant flow path 24 is formed. Coolant is supplied to the coolant flow path 24 from a chiller unit provided outside the processing container 12 via a pipe 26a. The coolant supplied to the coolant flow path 24 is returned to the chiller unit via a pipe 26b.

A shower head 30 is provided in the processing container 12. The shower head 30 is disposed above the stage 16 so as to face the stage 16. The stage 16 and the shower head 30 are provided substantially parallel to each other. The shower head 30 and the stage 16 function as a pair of electrodes (an upper electrode and a lower electrode).

In addition, the shower head 30 is supported in an upper portion of the processing container 12 via an insulating blocking member 32. The shower head 30 includes a ceiling plate 34 disposed to face the stage 16 and a support 36 supporting the ceiling plate 34.

The ceiling plate 34 is disposed to face the stage 16, and a plurality of gas holes 34a are formed in the ceiling plate 34 to eject processing gases into the processing container 12. The ceiling plate 34 is formed of, for example, silicon or SiC.

The support 36 is made of a conductive material (e.g., aluminum having an anodized surface), and is configured to detachably support the ceiling plate 34 on a lower portion thereof.

A gas diffusion space 36a is formed inside the support 36 so as to supply the processing gas to a plurality of gas holes 34a. A plurality of gas flow holes 36b are formed in a bottom portion of the support 36 so as to be located below the gas diffusion chamber 36a. The plurality of gas flow holes 36b communicate with the plurality of gas holes 34a, respectively.

The support 36 is formed with a gas inlet 36c for introducing the processing gas into the gas diffusion chamber 36a. A gas supply pipe 38 is connected to the gas inlet 36c.

To the gas supply pipe 38, a gas source group 40 is connected through a valve group 42 and a flow rate controller group 44. The valve group 42 has a plurality of opening/closing valves. The flow rate controller group 44 has a plurality of flow rate controllers such as mass flow controllers. In addition, the gas source group 40 has gas sources for a plurality of types of gases required for plasma processing. The plurality of gas sources of the gas source group 40 are connected to the gas supply pipe 38 via corresponding opening/closing valves and corresponding mass flow controllers, respectively.

In the plasma processing apparatus 10, one or more gases selected from the plurality of gas sources of the gas source group 40 are supplied to the gas supply pipe 38. The gases supplied to the gas supply pipe 38 reach the gas diffusion chamber 36a and are diffused and jetted into the processing space S in the form of a shower through the gas flow holes 36b and the gas holes 34a.

The shower head 30 is provided with a temperature adjustment mechanism for temperature adjustment. For example, a flow path 92 is formed inside the support 36. The plasma processing apparatus 10 is configured such that the temperature of the shower head 30 can be controlled by circulating, for example, a heat medium (such as brine) in the flow path 92. The flow path 92 is connected to the chiller unit provided outside the processing container 12 through a pipe, and thus the heat medium is circulated and supplied. That is, a circulation flow path for circulating the heat medium in the shower head 30 is formed by the flow path 92, the pipe, and the chiller unit. Details of the circulation flow path will be described below. The heat medium is, for example, a liquid containing carbon. As the liquid containing carbon, for example, ethylene glycol or alcohol may be used.

A first RF power supply 61 is electrically connected to the shower head 30 as the upper electrode via a low-pass filter (LPF) (not illustrated), a matcher MU1, and a power-feeding rod 60. The first high-frequency power supply 61 is a power supply for plasma generation, and supplies RF power having a frequency of 13.56 MHz or higher (e.g., 60 MHz) to the shower head 30. The matcher MU1 matches a load impedance with the internal (or output) impedance of the first high-frequency power supply 61. The matcher MU1 functions such that the output impedance of the first high-frequency power supply 61 apparently coincides with the load impedance in a state where plasma is generated in the processing container 12. The output terminal of the matcher MU1 is connected to an upper end of the power-feeding rod 60.

A second high-frequency power supply 62 is electrically connected to the stage 16 as the upper electrode via a low-pass filter (LPF) (not illustrated) and a matcher MU2. The second high-frequency power supply 62 is a power supply for ion attraction (for bias), and supplies RF power having a frequency in the range of 300 kHz to 13.56 MHz (e.g., 2 MHz) to the stage 16. The matcher MU2 matches a load impedance to the internal (or output) impedance of the second high-frequency power supply 62. The matcher MU2 functions such that the output impedance of the second high-frequency power supply 62 apparently coincides with the internal impedance in a state where plasma is generated in the processing container 12.

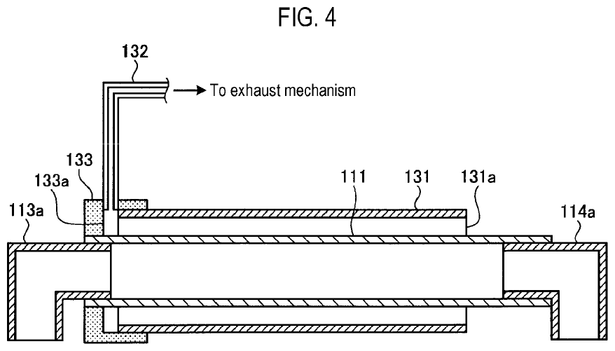

The shower head 30 and a portion of the power-feeding rod 60 is covered by a substantially cylindrical upper housing 12a extending upward from the sidewall of the processing container 12 above the height position of the shower head 30. The upper housing 12a is formed of a conductive material such as aluminum, and is grounded via the processing container 11. In a space surrounded by the upper housing 12a and the shower head 30, various parts (e.g., a pipe 111 and a cover 131 (see FIG. 4) described below) are disposed.

In addition, in the plasma processing apparatus 10, a deposition shield 46 is detachably provided along the inner wall of the processing container 12. In addition, the deposition shield 46 is also provided on an outer periphery of the support 14. The deposition shield 46 prevents an etching byproduct (deposition) from adhering to the processing container 12, and may be configured by coating an aluminum material with ceramic such as Y₂O₃.

At a portion near the bottom of the processing container 12, an exhaust plate 48 is provided between the support 14 and the inner wall of the processing container 12. The exhaust plate 48 is configured by coating, for example, an aluminum material with ceramic such as Y₂O₃. The processing container 12 is provided with an exhaust port 12e below the exhaust plate 48. An exhaust apparatus 50 is connected to the exhaust port 12e via an exhaust pipe 52. The exhaust apparatus 50 includes a vacuum pump such as a turbo molecular pump. When plasma processing is performed, the exhaust apparatus 50 depressurizes the inside of the processing container 12 to a desired degree of vacuum. In addition, a loading/unloading port 12g for a wafer W is provided in the side wall of the processing container 12. The loading/unloading port 12g is configured to be opened/closed by a gate valve 54.

As described above, the operation of the plasma processing apparatus 10 configured as described above is totally controlled by a controller 100. The controller 100 is, for example, a computer, and controls each part of the plasma processing apparatus 10. The operation of the plasma processing apparatus 10 is totally controlled by the controller 100.

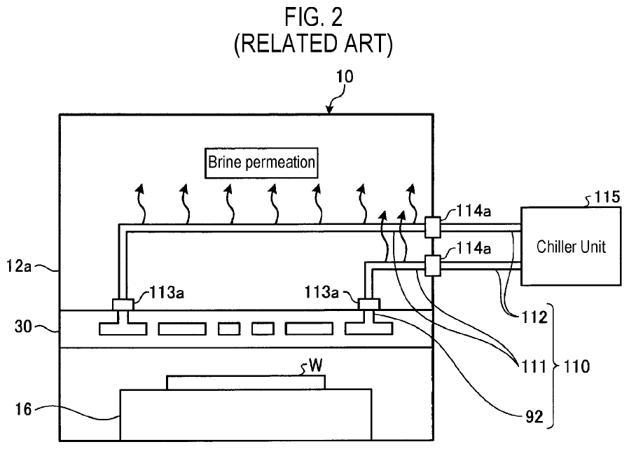

On the other hand, the plasma processing apparatus 10 is provided with a circulation flow path for circulating the heat medium to the temperature control target member. FIG. 2 is a view schematically illustrating a conventional circulation flow path for circulating a heat medium in which a shower head 30 is used as a temperature control target member. In FIG. 2, a circulation flow path 110 for circulating brine in the shower head 30 of the plasma processing apparatus 10 is schematically illustrated. The circulation flow path 110 is formed by a flow path 92, a pipe 111, and an outer pipe 112. The flow path 92 is formed inside the shower head 30 (the support 36), and the brine flows therein. The pipe 111 is formed of a flexible resin and is disposed in the upper housing 12a. One end of the pipe 111 is connected to the inner flow path 92 of the shower head 30 through the joint 113a, and the other end of the pipe 111 is connected to one end of the outer pipe 112 through the joint 114a provided in the upper housing 12a. The outer pipe 112 is formed of metal, such as stainless steel, and is disposed outside the upper housing 12a. One end of the outer pipe 112 is connected to the pipe 111 via a joint 114a provided in the upper housing 12a, and the other end of the outer pipe 112 is connected to the chiller unit 115.

The chiller unit 115 has a built-in reservoir tank for storing the brine. The reservoir tank is able to control the brine stored therein to a desired temperature. The chiller unit 115 transmits the brine stored in the reservoir tank to one end of the circulation flow path 110, and recovers the brine flowing out from the other end of the circulation flow path 110 to the reservoir tank. As a result, the chiller unit 115 circulates the brine in the circulation flow path 110 so as to control the temperature of the shower head 30 in which the circulation flow path 110 is formed.

When the brine flows in the resin pipe 111, as illustrated in FIG. 2, the brine permeates through the pipe 111 and is released as gas around the pipe 111. In particular, when the brine is controlled to a temperature higher than 100 degrees C. by the chiller unit 115, the brine tends to easily permeate through the pipe 111. FIG. 2 illustrates the state in which the brine permeates through the pipe 111 and is released as gas around the pipe 111 in the upper housing 12a. When the upper housing 12a is detached away for maintenance or the like, the brine released as gas may diffuse into a clean room, which is the installation location of the plasma processing apparatus 10, and contamination in the clean room may occur.

Otherwise, it is conceivable to airtightly surround the outer circumferential surface of the resin pipe 111 by a tubular cover and to connect an exhaust pipe to the airtight space between the pipe 111 and the cover so that the brine permeating and released through the pipe 111 is exhausted from the exhaust pipe. However, when the brine is exhausted from the exhaust pipe connected to the airtight space between the resin pipe 111 and the cover, the resin pipe 111 and the cover come to close to each other, causing the space serving as the flow path of the brine to shrink, which results in pressure loss in the space. In addition, since it is difficult to dispose the pump in the vicinity of the upper housing 12a, it is inevitable for the exhaust pipe connecting the airtight space and the exhaust pipe connecting the pump to be long. As a result, there is a possibility that the exhaust efficiency of the brine permeating through the resin pipe 111 decreases.

Thus, in the plasma processing apparatus 10 of the present embodiment, an air supply port is provided in the cover surrounding the outer circumferential surface of the resin pipe 111, and while the heat medium is exhausted from the exhaust pipe, air is introduced into the space between the pipe 111 and the cover.

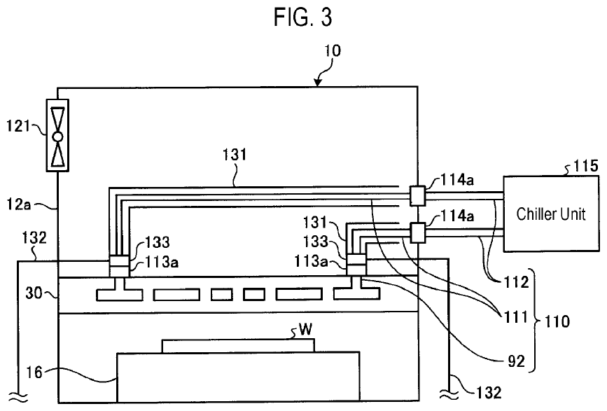

FIGS. 3 and 4 are views schematically illustrating the configuration of a pipe 111 in the embodiment. The pipe 111 forms at least a portion of a circulation flow path 110 that circulates brine, for example, as a heat medium to the shower head 30 as a temperature control target. The pipe 111 is formed of a highly flexible resin and is disposed in the upper housing 12a. One end of the pipe 111 is connected to a flow path 92 inside the shower head 30 via a joint 113a, and the other end of the pipe 111 is connected to one end of the outer pipe 112 via a joint 114a provided in the upper housing 12a.

On the outer circumferential surface of the pipe 111, a tubular cover 131 is provided to surround the outer circumferential surface of the pipe 111. The cover 131 is formed of a highly flexible resin. The resin forming the cover 131 may be the same as or different from the resin forming the pipe 111. A space is formed between the pipe 111 and the cover 131.

An exhaust pipe 132 is connected to the space between the pipe 111 and the cover 131. Specifically, the exhaust pipe 132 is connected to a closing member 133 that closes the space between the pipe 111 and the cover 131 provided on one end side of the cover 131, and communicates with the space between the pipe 111 and the cover 131 via a buffer space 133a formed in the closing member 133. An exhaust mechanism is connected to the exhaust pipe 132. The exhaust mechanism may be the exhaust apparatus 50 or an exhaust apparatus different from the exhaust apparatus 50. The permeating gas that permeates through the pipe 111 and is released into the space between the pipe 111 and the cover 131 is exhausted from the exhaust pipe 132.

In addition, the cover 131 has an air supply port 131a that introduces air into the space between the pipe 111 and the cover 131 while the permeating gas is exhausted from the exhaust pipe 132. Specifically, the cover 131 has the closing member 133 on its one end and has the air supply port 131a on the other end thereof, which is located opposite to the one end. In the present embodiment, the air supply port 131a is an open end formed by opening the other end of the cover 131. In addition, the cover 131 may have a shape such that the width thereof increases toward the air supply port 131a. In addition, the air supply port 131a does not necessarily need to be an open end, and may be a through hole penetrating the cover 131 in the thickness direction. In addition, a plurality of air supply ports 131a may be provided at the other end of the cover 131. For example, an air supply port 131a as an open end and an air supply port 131a as a through hole may be provided at the other end of the cover 131.

When the permeating gas is exhausted from the exhaust pipe 132, air is introduced into the space between the pipe 111 and the cover 131 from the air supply port 131a. As a result, an increase in the pressure loss in the space between the pipe 111 and the cover 131 is suppressed. In addition, the air introduced from the air supply port 131a pushes out the permeating gas, which permeates through the pipe 111 and is released into the space between the pipe 111 and the cover 131, toward the exhaust pipe 132. As a result, it is possible to improve the efficiency of exhausting the brine permeating through the resin pipe 111.

In addition, in the plasma processing apparatus 10 of the present embodiment, the pressure in the space in which the pipe 111 and the cover 131 are disposed (that is, the space surrounded by the upper housing 12a and the shower head 30) is maintained at a positive pressure. For example, by providing a fan 121 in the upper housing 12a so as to send outside air into the upper housing 12a, it is possible to make the pressure in the upper housing 12a higher than the pressure outside the upper housing 12a. In addition, for example, a pressure gauge may be provided in the upper housing 12a so as to measure the pressure in the space surrounded by the upper housing 12a and the shower head 30, and blowing from the fan 121 may be controlled by the controller 100 such that the pressure in the space becomes a positive pressure. As a result, a large amount of air is introduced into the space between the pipe 111 and the cover 131 from the space in which the pipe 111 and the cover 131 are disposed through the air supply port 131a in the cover 131. Thus, it is possible to further improve the efficiency of exhausting the permeating gas.

As described above, the plasma processing apparatus 10 according to the present embodiment has the resin pipe 111 forming at least a portion of the circulation flow path for circulating the heat medium to the shower head 30. The plasma processing apparatus 10 includes the cover 131 surrounding the outer circumferential surface of the pipe 111, and an exhaust pipe connected to the space between the pipe 111 and the cover 131 and configured to exhaust the heat medium, which permeates and is released through the pipe 111. In addition, the cover 131 has the air supply port 131a that introduces air into the space between the pipe 111 and the cover 131 while the permeating gas is exhausted from the exhaust pipe 132. As a result, the plasma processing apparatus 10 can improve the efficiency of exhausting the heat medium (permeating gas) permeating through the resin pipe 111. In addition, since the plasma processing apparatus 10 is able to efficiently exhaust the heat medium permeating through the resin pipe 111, the amount of the heat medium released to the outside of the plasma processing apparatus 10 can be reduced. Consequently, it is possible to suppress environmental pollution attributable to the heat medium.

In the plasma processing apparatus 10, the exhaust pipe 132 is connected to the closing member 133, which is provided at one end of the cover 131 and closes the space between the pipe 111 and the cover 131, and communicates with the space via the buffer space 133a formed in the closing member 133. The cover 131 has the air supply port 131a at the other end thereof, which is located opposite the one end at which the closing member 133 is provided. As a result, the plasma processing apparatus 10 is able to cause the air, which is introduced into the space between the pipe 111 and the cover 131 from the air supply port 131a, to flow from one end of the cover 131 toward the other end, whereby the heat medium can be efficiently pushed toward the exhaust pipe 132 by the air.

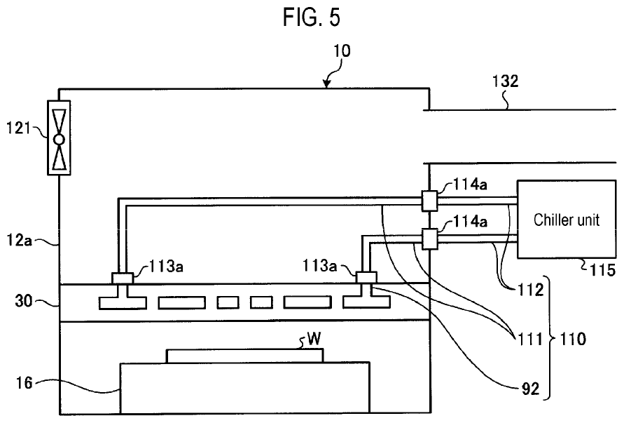

In the examples illustrated in FIGS. 3 and 4, a tubular cover made of a resin is used, but the present disclosure is not limited thereto. FIG. 5 is a view illustrating a modification of a cover. The example illustrated in FIG. 5 is an example in which the upper housing 12a is used as a cover. The upper housing 12a is provided with a fan 121 as an air supply port, and an exhaust pipe 132 connected to the exhaust apparatus is connected at a position facing the fan 121. Since the air introduced into the upper housing 12a from the fan 121 flows toward the exhaust pipe 132, the air is able to efficiently push the heat medium, which permeates the resin pipe 111 and stays in the upper housing 12a.

The above-described plasma processing apparatus 10 may be, for example, a CCP type plasma etching apparatus, but may be employed in any plasma processing apparatus 10. For example, the plasma processing apparatus 10 is applicable to any of an inductively coupled plasma (ICP) type apparatus, a radial line slot antenna type apparatus, an electron cyclotron resonance plasma (ECR) type apparatus, and a helicon wave plasma (HWP) apparatus.

In addition, in the above-described embodiment, the case where the substrate processing apparatus is the plasma processing apparatus 10 is described as an example, but it may be applied to other semiconductor manufacturing apparatuses in which a chiller unit 115 is provided.

According to the present disclosure, it is possible to improve the efficiency of exhausting permeating gas that permeates through a resin pipe.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A heat medium circulation system comprising:
a resin pipe forming at least a portion of a circulation flow path for circulating a heat medium to a temperature control target;
a cover surrounding an outer peripheral surface of the resin pipe; and
an exhaust pipe connected to a space between the resin pipe and the cover so as to exhaust the heat medium permeating through the resin pipe and released to the space,
wherein the cover includes an air supply port configured to introduce air into the space between the resin pipe and the cover while the heat medium is exhausted from the exhaust pipe.

2. The heat medium circulation system of claim 1, wherein the cover is a tubular member formed of a resin.

3. The heat medium circulation system of claim 2, wherein the exhaust pipe is connected to a closing member provided at one end of the cover to close the space between the resin pipe and the cover, and communicates with the space through a buffer space formed in the closing member, and
the cover includes the air supply port at the other end, which is located opposite the one end at which the closing member is provided.

4. The heat medium circulation system of claim 3, wherein the air supply port is an open end portion formed by opening the other end of the cover.

5. The heat medium circulation system of claim 4, further comprising a housing covering the temperature control target,
wherein the resin pipe and the cover are disposed in a space surrounded by the housing and the temperature control target, and
a pressure in the space surrounded by the housing and the temperature control target is maintained at a positive pressure.

6. The heat medium circulation system of claim 5, wherein the resin pipe is connected to a flow path formed inside the temperature control target so as to circulate the heat medium in the flow path.

7. The heat medium circulation system of claim 6, wherein the heat medium is a liquid containing carbon.

8. The heat medium circulation system of claim 1, further comprising a housing covering the temperature control target,
wherein the resin pipe and the cover are disposed in a space surrounded by the housing and the temperature control target, and
a pressure in the space surrounded by the housing and the temperature control target is maintained at a positive pressure.

9. The heat medium circulation system of claim 1, wherein the cover is a housing covering the temperature control target.

10. The heat medium circulation system of claim 1, wherein the resin pipe is connected to a flow path formed inside the temperature control target so as to circulate the heat medium in the flow path.

11. The heat medium circulation system of claim 1, wherein the heat medium is a liquid containing carbon.

12. A substrate processing apparatus comprising a heat medium circulation system,
wherein the heat medium circulation system comprises:
a resin pipe forming at least a portion of a circulation flow path for circulating a heat medium to a temperature control target;
a cover surrounding an outer peripheral surface of the resin pipe; and
an exhaust pipe connected to a space between the resin pipe and the cover and configured to exhaust the heat medium permeating through the resin pipe and released to the space, and
wherein the cover includes an air supply port configured to introduce air into the space between the resin pipe and the cover while the heat medium is exhausted from the exhaust pipe.
